(19) United States
(12) Patent Application Publication
(10) Pub. No.: US 2026/0060011 A1
(43) Pub. Date: Feb. 26, 2026

(54) METHOD FOR MANUFACTURING ZEROTH INTERLAYER DIELECTRIC

(71) Applicant: Shanghai Huali Integrated Circuit Corporation, Shanghai (CN)

(72) Inventors: Yu Xia, Shanghai (CN); Ying Dong, Shanghai (CN); Changfeng Wang, Shanghai (CN)

(73) Assignee: Shanghai Huali Integrated Circuit Corporation, Shanghai (CN)

(21) Appl. No.: 19/234,631

(22) Filed: Jun. 11, 2025

(30) Foreign Application Priority Data
Aug. 20, 2024 (CN) 202411147063.X

(51) Int. Cl. H01L 21/285; H01L 21/02; H01L 21/3105; H01L 21/311; H10D 64/01; H10D 64/23; H10D 64/66

(52) U.S. Cl. CPC H01L 21/285; H01L 21/02167; H01L 21/0217; H01L 21/02271; H01L 21/02274; H01L 21/31053; H01L 21/31111; H10D 64/017; H10D 64/258; H10D 64/675

(57) ABSTRACT

Disclosed is a method for manufacturing a zeroth interlayer dielectric, including: step 1: providing a semiconductor substrate subjected to a process of forming a contact etch stop layer; step 2: performing a first deposition process using a HARP process, to form a first oxide layer fully filling a spacing region; step 3: polishing the first oxide layer using a first chemical mechanical polishing process; step 4: performing wet etch to lower a top surface of the first oxide layer and form a first groove at the top of the spacing region; step 5: performing a second deposition process using an HDP CVD process, to form a second oxide layer fully filling the first groove; and step 6: polishing the second oxide layer using a second chemical mechanical polishing process, which is stopped on a surface of a first gate material layer of a first gate structure.

### CROSS-REFERENCE TO RELATED APPLICATIONS

This application claims priority to Chinese patent application No. 202411147063.X, filed on Aug. 20, 2024, the disclosure of which is incorporated herein by reference in its entirety.

### TECHNICAL FIELD

The present disclosure relates to a method for manufacturing a semiconductor integrated circuit, and in particular, to a method for manufacturing a zeroth interlayer dielectric (ILD0).

### BACKGROUND

During development of the semiconductor industry, the size of a transistor shrinks continuously, and the number of transistors that can be accommodated on an integrated circuit doubles every 18 months. However, as the process technique proceeds to the 45 nm stage, a component in the transistor first reaching the limit is a gate dielectric. A conventional gate dielectric is silicon dioxide, which can no longer satisfy the requirements of improving the performance and reducing the volume of the transistor and is likely to result in problems such as a leakage current, thereby reducing the reliability of the transistor.

Based on above, a high-dielectric constant (K) metal gate (MG) comes into being. The high-K metal gate uses a metal oxide as a gate dielectric, making it possible to reduce the size of the transistor while gate capacitance is kept unchanged, and reduce a leakage current, a working voltage, and energy consumption. The Intel Corporation has adopted the high-K metal gate transistor technique in 45 nm process chips, i.e., Intel 45 nm high-K metal gate silicon process technique, which uses hafnium oxide as a gate dielectric of a high-K metal gate. This technique was widely used at that time.

However, there are some challenges and problems in the high-K metal gate dielectric. There is a problem of balancing two major indicators of filling an insulating layer, i.e., a zeroth interlayer dielectric, between the metal gates, which are separately as follows:

(I) A final height of the metal gate is reduced.

The final height of the metal gate is related to the height of chemical mechanical polishing (CMP) of the ILD0 and the degree of a dishing depression. The ILD0 needs to be planarized by CMP after filling, in which case a dishing depression may be formed on the surface of the ILD0 between gate structures, and too big or too many dishing depressions may result in a dishing problem, i.e., a dishing defect.

If too many dishing depressions are produced in the CMP of the ILD0, a short circuit problem caused by a metal residue can only be avoided by subsequent CMP over-polishing of the metal gate, in which case the metal gate inevitably becomes shorter.

(II) A problem of an ILD0 void occurs.

After a distance between the metal gates becomes smaller, the insulating layer, i.e., ILD0, cannot fully fill a spacing region between the gate structures, and thus a void is formed inside the ILD0, in which case a metal material may fill the void inside the ILD0 in subsequent growth of a metal material layer of the metal gate.

In a subsequent contact (CT) formation process, etching is performed to form a contact opening, where contact openings at the top of a source region and a drain region on two sides of the metal gate need to pass through the ILD0. However, if there is a void inside the ILD0 and the void is filled with the metal material of the metal gate, in the process of etching the contact opening, the etching stops at the metal material in the void because the etching process can only etch an oxide layer corresponding to the ILD0 but cannot etch the metal material. The metal material in the void produces a CT block etch effect, such that the contact opening cannot pass through the ILD0 in a region with the void, and thus cannot achieve contact with a bottom doped region, such as the source region or the drain region. In order to eliminate the filled void inside the ILD0, it is necessary to change parameters of a deposition process for the ILD0, and finally, an improved process is likely to produce other side effects.

In an existing method, the ILD0 insulating layer is filled in two manners.

The first manner is forming the ILD0 by deposition using a high-density plasma (HDP) chemical vapor deposition (CVD) process.

The second manner is forming the ILD0 by deposition using a high aspect ratio process (HARP).

However, both manners have respective advantages and disadvantages, and neither can achieve an optimal effect.

The advantages of the HDP CVD process for forming the ILD0 by filling are:
good film quality, less CMP dishing, and a large MG height.

The disadvantages of the HDP CVD process for forming the ILD0 by filling are:
a poor filling effect, and a void easy to produce in the ILD0, which results in CT block etch and affects the yield.

If a radio frequency bias (RF bias) power is increased to improve the filling, it is likely to damage the edge of a wafer, resulting in a peeling defect.

The advantages of the HARP process for forming the ILD0 by filling are:
a strong filling capability and few voids.

The disadvantages of the HARP process for forming the ILD0 by filling are:
a soft film, and poor CMP dishing which affects the control of a final MG height.

### BRIEF SUMMARY

According to some embodiments in this application, a method for manufacturing a zeroth interlayer dielectric provided is disclosed in the following steps:
step 1: providing a semiconductor substrate subjected to a process of forming a contact etch stop layer, where a plurality of first gate structures are formed on a top surface of the semiconductor substrate, a region between the first gate structures is a spacing region, and the contact etch stop layer covers a top surface and a side surface of the first gate structure and a surface of the semiconductor substrate outside the first gate structure;
the first gate structure includes a first gate dielectric layer and a first gate material layer, where the first gate material layer is located on a top surface of the first gate dielectric layer, and a material of the first gate material layer is polysilicon or amorphous silicon;
step 2: performing a first deposition process to form a first oxide layer, where the first deposition process is a HARP process, and the first oxide layer fully fills the spacing region without a void and extends to the outside of the spacing region;
step 3: polishing the first oxide layer using a first chemical mechanical polishing process, which is stopped on a surface of the contact etch stop layer at the top of the first gate structure;
step 4: performing wet etch to lower the top surface of the first oxide layer in the spacing region and form a first groove at the top of the spacing region;
step 5: performing a second deposition process to form a second oxide layer, where the second deposition process is an HDP CVD process, and the second oxide layer fully fills the first groove and extends to the outside of the spacing region; and
step 6: polishing the second oxide layer using a second chemical mechanical polishing process, which is stopped on a surface of the first gate material layer, where the zeroth interlayer dielectric includes the first oxide layer and the second oxide layer retained in the spacing region.

In some cases, a sidewall is also formed on the side surface of the first gate structure.

In some cases, the sidewall includes a first-layer sidewall and a second-layer sidewall.

A first side surface of the first-layer sidewall is in contact with the side surface of the first gate structure, and a first side surface of the second-layer sidewall is in contact with a second side surface of the first-layer sidewall.

A second side surface of the second-layer sidewall is in contact with the contact etch stop layer.

In some cases, a material of the first-layer sidewall includes SiCN.

A material of the second-layer sidewall includes an oxide layer.

A material of the contact etch stop layer includes silicon nitride.

In some cases, an amount of the first oxide layer etched by the wet etch is such that a thickness of the second oxide layer retained after the subsequent second chemical mechanical polishing process is ensured as being 50 Å to 100 Å.

In some cases, a radio frequency bias (RF bias) power is set to 0 W in the second deposition process.

In some cases, the semiconductor substrate is a silicon substrate.

In some cases, a material of the first gate dielectric layer is an oxide layer; or the material of the first gate dielectric layer is a high-dielectric constant material.

In some cases, in step 1, a source region and a drain region are formed on the surface of the semiconductor substrate on two sides of the first gate structure.

In some cases, after step 6, the method further includes:
step 7: performing a metal gate replacement process, including:
removing the first gate structure and forming a gate trench; and
forming a second gate structure in the gate trench, where the second gate structure includes a second gate dielectric layer and a metal gate, the second gate dielectric layer is formed on the top surface of the semiconductor substrate, and the metal gate is located on a top surface of the second gate dielectric layer.

In some cases, a process of forming the metal gate includes:
depositing a metal material layer of the metal gate; and
polishing the metal material layer of the metal gate using a third chemical mechanical polishing process, where the third chemical mechanical polishing process removes the entire metal material layer of the metal gate on a surface of the zeroth interlayer dielectric in the spacing region, so that the metal material layer of the metal gate retained in the gate trench constitutes the metal gate.

In some cases, the method further includes:
step 8: forming a first interlayer dielectric, where the first interlayer dielectric is formed on a top surface of the metal gate and on a top surface of the zeroth interlayer dielectric; and
step 9: forming a plurality of contacts, where the contact at the top of the source region and the drain region sequentially passes through the first interlayer dielectric and the zeroth interlayer dielectric.

The contact at the top of the metal gate passes through the first interlayer dielectric.

The present disclosure implements filling of the zeroth interlayer dielectric using two deposition processes and two chemical mechanical polishing processes, where the first deposition process is the HARP process, so that the spacing region can be fully filled without a void due to the feature of a strong filling capability of the HARP process. Therefore, the present disclosure can realize void-free full filling of the spacing region between the gate structures.

Moreover, in the present disclosure, the first chemical mechanical polishing process is stopped on the surface of the contact etch stop layer, and in combination with the wet etch, can lower the top surface of the first oxide layer in the spacing region and form the first groove at the top of the spacing region. A depth of the first groove can be well controlled through the wet etch, so that the HDP CVD process, which has a weaker filling capacity than the HARP process, can also realize full filling of the first groove. However, since the quality of the second oxide layer formed by the HDP CVD process is better than the quality of the first oxide layer, a dishing depression formed on the top surface of the second oxide layer in the spacing region in the second chemical mechanical polishing process is reduced or eliminated, so that the dishing depression on the top surface of the second oxide layer results in no dishing defect, Therefore, the present disclosure can avoid forming a dishing defect at the top of the spacing region.

Since the present disclosure can avoid forming a dishing defect, in the metal gate replacement process, it is unnecessary to increase the amount of polishing in the third chemical mechanical polishing process in order to remove the dishing defect. Therefore, compared with an existing method having a dishing defect, the present disclosure can reduce the amount of polishing in the third chemical mechanical polishing process, ensuring the height of the metal gate, and thus improving the device performance.

Since the present disclosure can eliminate a void defect in the spacing region, filling a void defect with metal does not occur, so that metal block does not occur in a process of etching the contact at the top of a source-drain region, i.e., the source region and the drain region, enabling the contact in the source-drain region to completely pass through the zeroth interlayer dielectric, and thus avoiding a defect of a discontinuous contact.

In addition, since the second deposition process of the present disclosure only needs to realize complete filling of the first groove and the depth of the first groove is totally controllable, the requirement for a filling capacity of the second deposition process is greatly reduced. Compared with the existing method in which a large radio frequency bias power is required to increase the filling capacity in filling the spacing region using the HDP CVD process, the second deposition process of the present disclosure can reduce the radio frequency bias power to 0 W, i.e., no radio frequency bias is used, thereby completely eliminating damage to the edge of a wafer, i.e., a wafer edge, caused by the radio frequency bias, as well as a resultant peeling defect.

### BRIEF DESCRIPTION OF THE DRAWINGS

The present disclosure is further described in detail below with reference to the accompanying drawings and specific embodiments:

FIG. 1 is a flowchart of a method for manufacturing a zeroth interlayer dielectric according to an embodiment of the present disclosure; and

FIGS. 2A-2G are structural diagrams of devices in steps of the method for manufacturing a zeroth interlayer dielectric according to an embodiment of the present disclosure.

### DETAILED DESCRIPTION OF THE DISCLOSURE

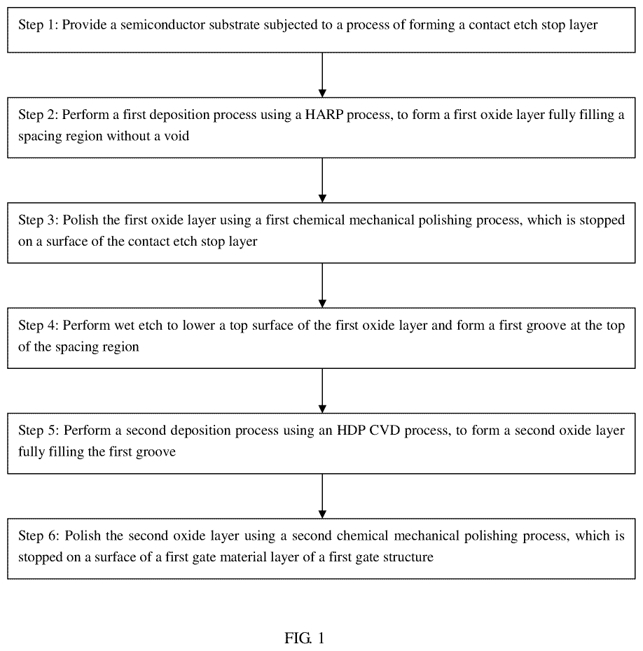

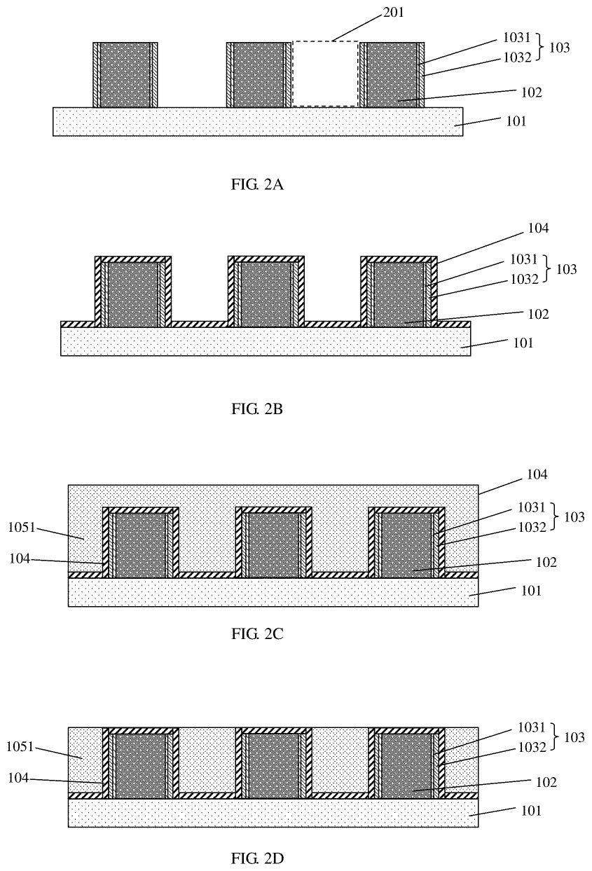

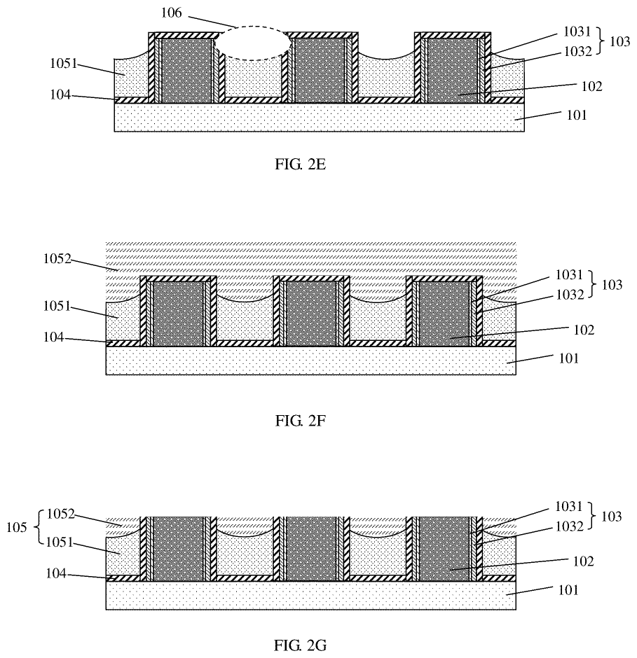

FIG. 1 is a flowchart of a method for manufacturing a zeroth interlayer dielectric 105 according to an embodiment of the present disclosure; and FIGS. 2A-2G are structural diagrams of devices in steps of the method for manufacturing a zeroth interlayer dielectric 105 according to an embodiment of the present disclosure. The method for manufacturing a zeroth interlayer dielectric 105 according to this embodiment of the present disclosure includes the following steps.

Step 1: Referring to FIG. 2B, a semiconductor substrate 101 subjected to a process of forming a contact etch stop layer 104 is provided.

After the contact etch stop layer 104 is formed, referring to FIG. 2A, a plurality of first gate structures 102 are formed on a top surface of the semiconductor substrate 101, a region between the first gate structures 102 is a spacing region 201, and the contact etch stop layer 104 covers a top surface and a side surface of the first gate structure 102 and a surface of the semiconductor substrate 101 outside the first gate structure 102.

The first gate structure 102 includes a first gate dielectric layer (not shown) and a first gate material layer (not shown), where the first gate material layer is located on a top surface of the first gate dielectric layer, and a material of the first gate material layer is polysilicon or amorphous silicon. The first gate dielectric layer is located on a top surface of the semiconductor substrate 101.

In some embodiments, the semiconductor substrate 101 is a silicon substrate.

In some embodiments, a material of the first gate dielectric layer is an oxide layer. In some embodiments, the material of the first gate dielectric layer may alternatively be a high-dielectric constant material.

The first gate structure 102 is used as a dummy gate structure for defining a formation region for a source region and a drain region.

Under self-alignment definition of the first gate structure 102, a source region (not shown) and a drain region (not shown) are formed on the surface of the semiconductor substrate 101 on two sides of the first gate structure 102.

A sidewall 103 is also formed on the side surface of the first gate structure 102. The sidewall 103 is formed on the side surface of the first gate structure 102 in a self-aligned manner.

The sidewall 103 includes a first-layer sidewall 1031 and a second-layer sidewall 1032.

A first side surface of the first-layer sidewall 1031 is in contact with the side surface of the first gate structure 102, and a first side surface of the second-layer sidewall 1032 is in contact with a second side surface of the first-layer sidewall 103.

A second side surface of the second-layer sidewall 1032 is in contact with the contact etch stop layer 104.

The source region and the drain region are self-aligned with the sidewall 103 on the side surface of the first gate structure 1022.

In some embodiments, a lightly doped drain (LDD) region self-aligned with the first-layer sidewall 1031 is also formed in a surface region of the semiconductor substrate 101 on the two sides of the first gate structure 102.

In some embodiments, an embedded epitaxial layer is also formed in the formation region for the source region and the drain region. The embedded epitaxial layer includes an epitaxial layer filling a source-drain trench, and the source-drain trench is self-aligned with the side surface of the second-layer sidewall 1032.

In some embodiments, a material of the first-layer sidewall 1031 includes SiCN.

A material of the second-layer sidewall 1032 includes an oxide layer.

A material of the contact etch stop layer 104 includes silicon nitride.

Step 2: Referring to FIG. 2C, a first deposition process is performed to form a first oxide layer 1051, where the first deposition process is a HARP process, and the first oxide layer 1051 fully fills the spacing region 201 without a void and extends to the outside of the spacing region 201.

Compared with other existing deposition processes, the HARP process has a good void filling capability, so that the spacing region 201 may be fully filled without a void using the void filling capability of the HARP process. That is, in the spacing region 201, no void is formed inside the first oxide layer 1051, thereby eliminating a defect caused by a void inside the first oxide layer 1051. Such a defect is mainly reflected as blocking further etching of the first oxide layer 1051 at the bottom of the void in subsequent etching of the contact, finally preventing the contact from making contact with a bottom doped region such as the source region or drain region.

Step 3: Referring to FIG. 2D, the first oxide layer 1051 is polished using a first chemical mechanical polishing process, which is stopped on a surface of the contact etch stop layer 104 at the top of the first gate structure 102.

In this embodiment of the present disclosure, an end point of the first chemical mechanical polishing process may be controlled using a difference between materials of the contact etch stop layer 104 and the first oxide layer 1051, so that the polishing is stopped on the surface of the contact etch stop layer 104 at the top of the first gate structure 102. In this way, referring to FIG. 2D, the first oxide layer 1051 on the top surface of the contact etch stop layer 104 at the top of the first gate structure 102 is completely removed, and the contact etch stop layer 104 is also partially removed, thereby lowering the top surface of the contact etch stop layer 104 to some extent. Moreover, a top surface of the first oxide layer 1051 in the spacing region 201 is lowered as being flush with or lower than the top surface of the contact etch stop layer 104. In addition, due to the feature of the HARP process, a film of the first oxide layer 1051 is soft, and is easier to remove during the first chemical mechanical polishing process, thus forming a recessed dishing depression (not shown). That is, the top surface of the first oxide layer 1051 in a region shown in FIG. 2D is flat. However, in practice, there are a number of dishing depressions in some regions not shown. Since an adverse impact of the dishing depression is completely overcome in this embodiment of the present disclosure, a schematic structural diagram of a region with a dishing defect is not particularly shown in FIG. 2D.

Step 4: Referring to FIG. 2E, wet etch is performed to lower the top surface of the first oxide layer 1051 in the spacing region 201 and form a first groove at the top of the spacing region 201, the first groove having a structure as shown in the dashed line box 106.

In some embodiments, the wet etch may be realized using a hydrofluoric acid etch solution.

In some embodiments, an amount of the first oxide layer 1051 etched by the wet etch is such that a thickness of the second oxide layer 1052 retained after the subsequent second chemical mechanical polishing process is ensured as being 50 Å to 100 Å. In this way, it may be ensured that the first groove has a small depth to facilitate the subsequent filling with the second oxide layer 1052, and also ensured that the first groove has a depth sufficient to prevent the second oxide layer 1052 from being completely consumed in the subsequent second chemical mechanical polishing process.

Step 5: Referring to FIG. 2F, a second deposition process is performed to form a second oxide layer 1052, where the second deposition process is an HDP CVD process, and the second oxide layer 1052 fully fills the first groove and extends to the outside of the spacing region 201.

In this embodiment of the present disclosure, a radio frequency bias (RF bias) power is set to 0 W in the second deposition process. Setting the radio frequency bias power to 0 W may prevent damage to a wafer edge, thus preventing a peeling defect caused by the damage to the wafer edge. The wafer edge is an edge region of a wafer including the semiconductor substrate 101.

In this embodiment of the present disclosure, compared with the HARP process, the HDP CVD process realizes filling of the second oxide layer 1052 with better film quality. Although the HDP CVD process has a poorer void filling capability than the HARP process, the second oxide layer 1052 only needs to fully fill the first groove, and does not need to fill a groove structure in the entire depth range of the spacing region. Therefore, the introduction of the HDP CVD process results in no void structure.

Moreover, the formation of a dishing defect in the subsequent second chemical mechanical polishing process may be avoided due to the better film quality of the second oxide layer 1052. In this embodiment of the present disclosure, the dishing defect refers to a dishing depression with a large size such as a large depth and a large width, and the dishing depression having a large size has a large impact on the height of the subsequent metal gate. If the dishing depression has a small size, no metal residue is formed in a subsequent metal gate process, and the height of the metal gate is not affected, thereby forming no defect. Therefore, the second oxide layer 1052 formed in this embodiment of the present disclosure may cause the size of the dishing depression in the subsequent second chemical mechanical polishing process to be reduced or directly eliminated, so that no dishing defect is produced. However, in the existing method, in order to ensure void-free filling, an oxide layer is formed using only the HARP process, in which case a large dishing depression is formed in a partial region of a wafer, thereby forming a defect, which ultimately affects the height of the subsequent metal gate.

step 6: Referring to FIG. 2G, the second oxide layer 1052 is polished using a second chemical mechanical polishing process, which is stopped on a surface of the first gate material layer, where the zeroth interlayer dielectric 105 includes the first oxide layer 1051 and the second oxide layer 1052 retained in the spacing region 201.

After step 6, the method further includes:
step 7: A metal gate replacement process is performed, including:
removing the first gate structure 102 and forming a gate trench (not shown); and
forming a second gate structure in the gate trench, where the second gate structure includes a second gate dielectric layer and a metal gate, the second gate dielectric layer is formed on the top surface of the semiconductor substrate 101, and the metal gate is located on a top surface of the second gate dielectric layer.

In some embodiments of the method, the second gate dielectric layer is still the first gate dielectric layer. In this case, during removal of the first gate structure 102, it is necessary to retain the first gate dielectric layer in these regions, and omit a process of forming the second gate dielectric layer during formation of the second gate structure.

In some embodiments of the method, during removal of the first gate structure 102, it is necessary to completely remove the first gate dielectric layer, and then form the second gate dielectric layer separately.

A process of forming the metal gate includes:
depositing a metal material layer of the metal gate; and
polishing the metal material layer of the metal gate using a third chemical mechanical polishing process, where the third chemical mechanical polishing process removes the entire metal material layer of the metal gate on a surface of the zeroth interlayer dielectric 105 in the spacing region 201, so that the metal material layer of the metal gate retained in the gate trench constitutes the metal gate.

In this embodiment of the present disclosure, since there is no dishing defect on the top surface of the zeroth interlayer dielectric 105 shown in FIG. 2G, in the process of depositing the metal material layer of the metal gate, the metal material layer extending to the top surface of the zeroth interlayer dielectric 105 is easy to remove in the third chemical mechanical polishing process, without increasing the amount of polishing in the third chemical mechanical polishing process, in which case the height of the metal gate can be maintained.

This embodiment of the present disclosure further includes the following steps:
Step 8: A first interlayer dielectric (not shown) is formed, where the first interlayer dielectric is formed on a top surface of the metal gate and on a top surface of the zeroth interlayer dielectric 105.
Step 9: A plurality of contacts are formed, where the contact at the top of the source region and the drain region sequentially passes through the first interlayer dielectric and the zeroth interlayer dielectric 105.

The contact at the top of the metal gate passes through the first interlayer dielectric.

A process of forming the contact includes performing etching to form a contact opening, and then filling the contact opening with metal to form the contact.

In the method of this embodiment of the present disclosure, there is no void in the zeroth interlayer dielectric 105 shown in FIG. 2G, so that in a process of forming the metal gate, the metal material layer of the metal gate cannot extend into the void. In this way, a process of etching the contact opening being blocked by metal in a void in the presence of the void may be avoided. Therefore, in this embodiment of the present disclosure, the process of etching the contact opening may ensure that the contact openings at the top of the source region and the drain region passes through the entire zeroth interlayer dielectric 105.

This embodiment of the present disclosure implements filling of the zeroth interlayer dielectric 105 using two deposition processes and two chemical mechanical polishing processes, where the first deposition process is the HARP process, so that the spacing region 201 can be fully filled without a void due to the feature of a strong filling capability of the HARP process. Therefore, this embodiment of the present disclosure can realize void-free full filling of the spacing region 201 between the gate structures.

Moreover, in this embodiment of the present disclosure, the first chemical mechanical polishing process is stopped on the surface of the contact etch stop layer 104, and in combination with the wet etch, can lower the top surface of the first oxide layer 1051 in the spacing region 201 and form the first groove at the top of the spacing region 201. A depth of the first groove can be well controlled through the wet etch, so that the HDP CVD process, which has a weaker filling capacity than the HARP process, can also realize full filling of the first groove. However, since the quality of the second oxide layer 1052 formed by the HDP CVD process is better than the quality of the first oxide layer 1051, a dishing depression formed on the top surface of the second oxide layer 1052 in the spacing region 201 in the second chemical mechanical polishing process is reduced or eliminated, so that the dishing depression on the top surface of the second oxide layer 1052 results in no dishing defect, Therefore, this embodiment of the present disclosure can avoid forming a dishing defect at the top of the spacing region 201.

Since this embodiment of the present disclosure can avoid forming a dishing defect, in the metal gate replacement process, it is unnecessary to increase the amount of polishing in the third chemical mechanical polishing process in order to remove the dishing defect. Therefore, compared with an existing method having a dishing defect, this embodiment of the present disclosure can reduce the amount of polishing in the third chemical mechanical polishing process, ensuring the height of the metal gate, and thus improving the device performance.

Since this embodiment of the present disclosure can eliminate a void defect in the spacing region 201, filling a void defect with metal does not occur, so that metal block does not occur in a process of etching the contact at the top of a source-drain region, i.e., the source region and the drain region, enabling the contact in the source-drain region to completely pass through the zeroth interlayer dielectric 105, and thus avoiding a defect of a discontinuous contact.

In addition, since the second deposition process of this embodiment of the present disclosure only needs to realize complete filling of the first groove and the depth of the first groove is totally controllable, the requirement for a filling capacity of the second deposition process is greatly reduced. Compared with the existing method in which a large radio frequency bias power is required to increase the filling capacity in filling the spacing region 201 using the HDP CVD process, the second deposition process of this embodiment of the present disclosure can reduce the radio frequency bias power to 0 W, i.e., no radio frequency bias is used, thereby completely eliminating damage to the edge of a wafer, i.e., a wafer edge, caused by the radio frequency bias, as well as a resultant peeling defect.

The present disclosure is described in detail above through specific embodiments, which, however, do not impose limitations to the present disclosure. Without departing from the principle of the present disclosure, a person skilled in the art may also made many other deformations and improvements, which should also be considered as the protection scope of the present disclosure.

What is claimed is:

1. A method for manufacturing a zeroth interlayer dielectric, comprising the following steps:
step 1: providing a semiconductor substrate subjected to a process of forming a contact etch stop layer, wherein a plurality of first gate structures are formed on a top surface of the semiconductor substrate, a region between the first gate structures is a spacing region, and the contact etch stop layer covers a top surface and a side surface of the first gate structure and a surface of the semiconductor substrate outside of the first gate structure;
the first gate structure comprises a first gate dielectric layer and a first gate material layer, wherein the first gate material layer is located on a top surface of the first gate dielectric layer, and a material of the first gate material layer is polysilicon or amorphous silicon;
step 2: performing a first deposition process to form a first oxide layer, wherein the first deposition process is a high aspect ratio process (HARP), and the first oxide layer fully fills the spacing region without a void and extends to the outside of the spacing region;
step 3: polishing the first oxide layer using a first chemical mechanical polishing process, which is stopped on a surface of the contact etch stop layer at the top of the first gate structure;
step 4: performing wet etch to lower the top surface of the first oxide layer in the spacing region and form a first groove at the top of the spacing region;
step 5: performing a second deposition process to form a second oxide layer, wherein the second deposition process is a high-density plasma (HDP) chemical vapor deposition (CVD) process, and the second oxide layer fully fills the first groove and extends to the outside of the spacing region; and
step 6: polishing the second oxide layer using a second chemical mechanical polishing process, which is stopped on a surface of the first gate material layer, wherein the zeroth interlayer dielectric comprises the first oxide layer and the second oxide layer retained in the spacing region.

2. The method for manufacturing the zeroth interlayer dielectric according to claim 1, wherein a sidewall is also formed on the side surface of the first gate structure.

3. The method for manufacturing the zeroth interlayer dielectric according to claim 2, wherein the sidewall comprises a first-layer sidewall and a second-layer sidewall;
a first side surface of the first-layer sidewall is in contact with the side surface of the first gate structure, and a first side surface of the second-layer sidewall is in contact with a second side surface of the first-layer sidewall; and
a second side surface of the second-layer sidewall is in contact with the contact etch stop layer.

4. The method for manufacturing the zeroth interlayer dielectric according to claim 3, wherein a material of the first-layer sidewall comprises SiCN, a material of the second-layer sidewall comprises an oxide layer, and a material of the contact etch stop layer comprises silicon nitride.

5. The method for manufacturing the zeroth interlayer dielectric according to claim 4, wherein an amount of the first oxide layer etched by the wet etch is such that a thickness of the second oxide layer retained after the subsequent second chemical mechanical polishing process is ensured as being 50 Å to 100 Å.

6. The method for manufacturing the zeroth interlayer dielectric according to claim 1, wherein a radio frequency bias power is set to 0 W in the second deposition process.

7. The method for manufacturing the zeroth interlayer dielectric according to claim 1, wherein the semiconductor substrate is a silicon substrate.

8. The method for manufacturing the zeroth interlayer dielectric according to claim 7, wherein a material of the first gate dielectric layer is an oxide layer, or the material of the first gate dielectric layer is a high-dielectric constant material.

9. The method for manufacturing the zeroth interlayer dielectric according to claim 8, wherein, in step 1, a source region and a drain region are formed on the surface of the semiconductor substrate on two sides of the first gate structure.

10. The method for manufacturing the zeroth interlayer dielectric according to claim 9, after step 6, further comprising:
step 7: performing a metal gate replacement process, comprising:
removing the first gate structure and forming a gate trench; and
forming a second gate structure in the gate trench, wherein the second gate structure comprises a second gate dielectric layer and a metal gate, the second gate dielectric layer is formed on the top surface of the semiconductor substrate, and the metal gate is located on a top surface of the second gate dielectric layer.

11. The method for manufacturing the zeroth interlayer dielectric according to claim 10, wherein a process of forming the metal gate comprises:
depositing a metal material layer of the metal gate; and
polishing the metal material layer of the metal gate using a third chemical mechanical polishing process, wherein the third chemical mechanical polishing process removes the entire metal material layer of the metal gate on a surface of the zeroth interlayer dielectric in the spacing region, so that the metal material layer of the metal gate retained in the gate trench constitutes the metal gate.

12. The method for manufacturing the zeroth interlayer dielectric according to claim 10, further comprising:
step 8: forming a first interlayer dielectric, wherein the first interlayer dielectric is formed on a top surface of the metal gate and on a top surface of the zeroth interlayer dielectric; and
step 9: forming a plurality of contacts, wherein the contact at the top of the source region and the drain region sequentially passes through the first interlayer dielectric and the zeroth interlayer dielectric, and wherein the contact at the top of the metal gate passes through the first interlayer dielectric.
